(19) United States
(12) Patent Application Publication
(10) Pub. No.: US 2023/0245904 A1
(43) Pub. Date: Aug. 3, 2023

(54) NOZZLE ASSEMBLY AND SEMICONDUCTOR EQUIPMENT ADOPTING THE NOZZLE ASSEMBLY

(71) Applicant: CHANGXIN MEMORY TECHNOLOGIES, INC., Hefei City, Anhui (CN)

(72) Inventor: Haodong LIU, Hefei City, Anhui (CN)

(73) Assignee: CHANGXIN MEMORY TECHNOLOGIES, INC., Hefei City, Anhui (CN)

(21) Appl. No.: 17/614,651

(22) PCT Filed: May 31, 2021
(86) PCT No.: PCT/CN2021/097332

§ 371 Date: Nov. 29, 2021

(30) Foreign Application Priority Data
Oct. 20, 2020 (CN) 202011122385.0

(51) Int. Cl. H01L 21/67

(52) U.S. Cl. CPC H01L 21/67051; H01L 21/6715

(57) ABSTRACT

The present disclosure provides a nozzle assembly and a semiconductor equipment adopting the nozzle assembly. The nozzle assembly includes: at least two nozzles; at least one spacer, connecting two adjacent nozzles so that the distance between the two adjacent nozzles is within a preset range; and a robot arm, connected with one of the nozzles and configured to drive the at least two nozzles to move.

### CROSS-REFERENCE TO RELATED APPLICATIONS

The present disclosure claims priority to Chinese Patent Application No. 202011122385.0, entitled “Nozzle assembly and semiconductor equipment adopting the nozzle assembly”, filed to China National Intellectual Property Administration on Oct. 20, 2020, which is incorporated herein by reference in its entirety.

### TECHNICAL FIELD

The present disclosure relates to, but is not limited to, a nozzle assembly and a semiconductor equipment adopting the nozzle assembly.

### BACKGROUND

In the semiconductor manufacturing process, it is usually necessary to clean the surface of the wafer to remove impurities (for example, organics, particles or peeled films) on the surface of the wafer. For example, in the semiconductor manufacturing process, particles are generated at the edge of the wafer, and these particles may move on the surface of the wafer, for example, to the center of the wafer, causing the reduced yield of wafers. In addition, on the slope of the wafer edge, there may be film peeling and the peeled film may move to the center of the wafer, which will also cause the reduced yield of wafers. Therefore, the wafer needs to be cleaned to remove particles or peeled films.

However, the existing cleaning methods are less effective and unsatisfactory.

### SUMMARY

The following is a summary of the subject matter detailed herein. This summary is not intended to limit the protection scope defined by the claims.

The nozzle assembly and the semiconductor equipment adopting the nozzle assembly according to the present disclosure can improve the cleaning effect and improve the yield of wafers.

The present disclosure provides a nozzle assembly, comprising: at least two nozzles; at least one spacer, connecting two adjacent nozzles so that the distance between the two adjacent nozzles is within a preset range; and a robot arm, connected with one of the nozzles and configured to drive the at least two nozzles to move.

In some embodiments, the spacer has a fixed length.

In some embodiments, the spacer is a telescopic structure with a variable length.

In some embodiments, the preset range of the distance is 0.4 mm to 1 mm.

In some embodiments, the nozzle assembly further comprises a plurality of liquid channels and each nozzle is in connected with at least one of the liquid channels.

In some embodiments, the nozzle comprises a chemical cleaning liquid nozzle, and the chemical cleaning liquid nozzle is in connected with two liquid channels to respectively feed cleaning water and chemical cleaning liquid to the chemical cleaning liquid nozzle.

In some embodiments, a heating element is provided on the outer surface of at least one of the nozzles to heat the cleaning liquid flowing through the nozzle.

In some embodiments, the heating element is a heating wire and the heating wire is wound on the outer surface of the nozzle.

In some embodiments, the heating temperature of the heating element is 40° C. to 60° C.

The present disclosure further provides a semiconductor equipment comprising the nozzle assembly as described above.

The advantage of the present disclosure is that a spacer is provided between adjacent nozzles to maintain the distance between two adjacent nozzles within a preset range, so as to prevent two adjacent nozzles from getting too close or too far during the manufacturing process. The cleaning effect of the wafer surface is improved, organics, particles or peeled films are effectively removed, and the yield of wafers is improved.

After reading and understanding the drawings and detailed description, other aspects may be understood.

### BRIEF DESCRIPTION OF THE DRAWINGS

The accompanying drawings, which are incorporated in and form a part of this specification, illustrate embodiments of the present disclosure and explain, together with the description, the principles of the present disclosure. In these drawings, like reference numerals identify like elements. The drawings to be described below are some, but not all, embodiments of the present disclosure. Other drawings may be obtained by a person of ordinary skill in the art in accordance with those drawings without paying any creative effort.

FIG. 1 is a schematic view of the movement trajectory of two adjacent nozzles in the prior art;

FIG. 2 is a schematic structure diagram of a nozzle assembly according to a first embodiment of the present disclosure, when viewed from the top;

FIG. 3 is a schematic structure diagram of the nozzle assembly according to a second embodiment of the present disclosure, when viewed from the top;

FIG. 4 is a schematic structure diagram of the nozzle assembly according to a third embodiment of the present disclosure, when viewed from the top; and

FIG. 5 is a schematic structure diagram of the nozzle assembly according to a fourth embodiment of the present disclosure, when viewed from the top.

### DETAILED DESCRIPTION

To make the purposes, technical solutions and advantages of the embodiments of the present disclosure clearer, the technical solutions in the embodiments of the present disclosure will be described clearly and completely with reference to the drawings in the embodiments of the present disclosure. Apparently, the embodiments to be described are some, but not all, embodiments of the present disclosure. Based on the embodiments of the present disclosure, all other embodiments obtained by a person of ordinary skill in the art without paying any creative effort should be included in the protection scope of the present disclosure. It is to be noted that the embodiments of the present disclosure and features in the embodiments may be combined if not conflict.

The specific implementation of the nozzle assembly and the semiconductor equipment adopting the nozzle assembly according to the present disclosure will be described below with reference to the accompanying drawings.

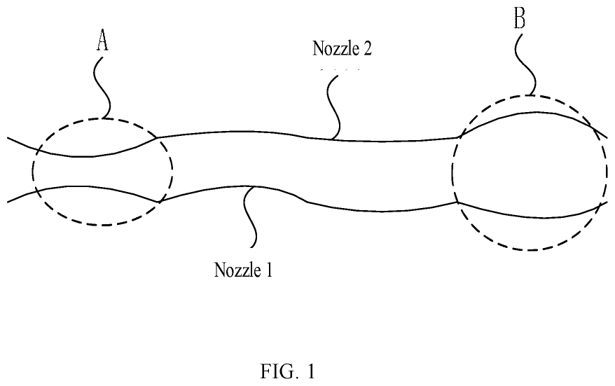

It was found that, when the surface of the wafer is cleaned by the nozzle assembly, two adjacent nozzles are controlled by their respective robot arms to move, resulting in an uncontrollable distance between two adjacent nozzles. FIG. 1 is a schematic view of the movement trajectory of two adjacent nozzles (nozzle 1 and nozzle 2). It may be known from FIG. 1 that, in some areas (area A indicated by the ellipse in FIG. 1), nozzle 1 is close to nozzle 2, while in some areas B (area B indicated by the ellipse in FIG. 1), nozzle 1 is far away from nozzle 2. The distance between two adjacent nozzles is uncontrollable. This will result in poor cleaning of the wafer surface, and organics, particles or peeled films will not be completely removed, resulting in the reduced yield of wafers.

Therefore, the present disclosure provides a nozzle assembly which can improve the cleaning effect of the wafer surface, effectively remove organics, particles or peeled films, and improve the yield of wafers.

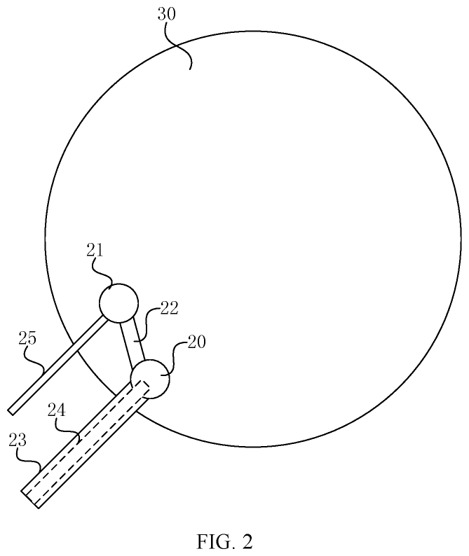

FIG. 2 is a schematic structure diagram of a nozzle assembly according to a first embodiment of the present disclosure, when viewed from the top. It is a top view relative to the wafer 30. Referring to FIG. 2, the nozzle assembly according to the present disclosure comprises at least two nozzles, at least one spacer, and a robot arm.

In this embodiment, the nozzle assembly comprises two nozzles: the first nozzle 20 and the second nozzle 21, respectively. The cleaning liquid sprayed by the first nozzle 20 and the second nozzle 21 may be different. For example, the first nozzle 20 is used to spray chemical cleaning liquid SC1 (a mixture of ammonia, hydrogen peroxide and water), and the second nozzle 21 is used to spray cleaning water, for example pure water. It may be understood that, in other embodiments of the present disclosure, the cleaning liquid sprayed by the first nozzle 20 and the second nozzle 21 may be other types of cleaning liquid. In other embodiments of the present disclosure, the nozzle assembly comprises three or more nozzles. The number of the nozzles may be set according to actual needs.

In this embodiment, the nozzle assembly comprises one spacer 22 that connects two adjacent nozzles. That is, the spacer 22 connects the first nozzle 20 and the second nozzle 21.

Due to the spacing effect of the spacer 22, the distance between two adjacent nozzles may be maintained within a preset range. Exemplarily, due to the spacing effect of the spacer 22, the distance between the first nozzle 20 and the second nozzle 21 may be maintained within a preset range. In other embodiments of the present disclosure, if the nozzle assembly comprises three nozzles, the nozzle assembly comprises two spacers to connect adjacent nozzles; and if the nozzle assembly comprises four nozzles, the nozzle assembly comprises three spacers to connect adjacent nozzles.

In this embodiment, the spacer 22 is a short rod. One end of the short rod is connected to the first nozzle 20, and the other end of the short rod is connected to the second nozzle 22, so that the distance between the first nozzle 20 and the second nozzle 21 is fixed. In other embodiments of the present disclosure, the spacer 22 may be in other structures, as long as the function of the spacer 22 may be realized, for example, a dumbbell-shaped connector with holes at both ends.

In the nozzle assembly according to the present disclosure, due to the spacer 22, no matter how two adjacent nozzles move, the distance between the two nozzles is always within a preset range. In this embodiment, due to the spacer 22, no matter how the adjacent first nozzle 20 and the second nozzle 21 move, the distance between the two nozzles is always maintained within a preset range.

In some embodiments, the preset range is 0.4 mm to 1 mm. If the preset range is too large, the assistant effect between the nozzles will be reduced. If the preset range is too small, the two nozzles will be too close, resulting in interference.

The distance between the two nozzles may always be within a preset range by adjusting the length of the spacer 22. In this embodiment, the spacer 22 has a fixed length, and the distance between the first nozzle 20 and the second nozzle 21 is the length of the spacer 22. By selecting a spacer 22 having a length within a preset range, the distance between the first nozzle 20 and the second nozzle 21 may be maintained within a preset range.

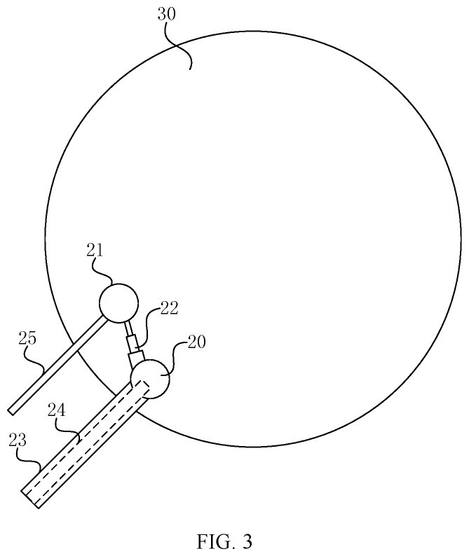

In one cleaning situation, it is desired to have a first distance between two adjacent nozzles, and in another cleaning situation, it is desired to have a second distance between two adjacent nozzles. That is, it is desired that the distance between two adjacent nozzles may be adjusted within a certain range to meet different needs. In view of this, in another embodiment of the present disclosure, referring to FIG. 3 which is a top view of the second embodiment of the present disclosure, the spacer 22 is a telescopic structure. That is, the length of the spacer 22 is variable. If it is desired to have a first distance between two adjacent nozzles, the spacer 22 is adjusted to the first distance and the first distance is maintained to avoid the change in distance between two adjacent nozzles during operation. If it is desired to have a second distance between two adjacent nozzles, the spacer 22 is adjusted to the second distance and the second distance is maintained to avoid the change in distance between two adjacent nozzles during operation. In the second embodiment, the spacer 22 may be a telescopic rod, which is not limited in the present disclosure.

Further referring to FIG. 2, the robot arm 23 is connected to one of the nozzles, and is used to drive the at least two nozzles to move. In the first embodiment, the robot arm 23 is connected to the first nozzle 20 but not to the second nozzle 21. The first nozzle 20 drives the second nozzle 21 through the spacer 22 to move, when the robot arm 23 controls the first nozzle 20 to move. In other embodiments of the present disclosure, if the nozzle assembly comprises three or more nozzles, the robot arm 23 is still connected to only one nozzle. That is to say, all the nozzles of the nozzle assembly are controlled by a robot arm 23. Compared with the prior art where each nozzle is controlled by a robot arm, the influence on the distance between the nozzles and their movement by the vibration and instability of the robot arm 23 is greatly reduced, and the cleaning effect is improved. Meanwhile, in the prior art, since each nozzle is controlled by a robot arm, the position of each nozzle needs to be calibrated during the cleaning process. In contrast, in the present disclosure, the position of only one of the nozzles needs to be calibrated. For example, the position of the first nozzle connected to the robot arm 23 is calibrated. The workload is reduced by at least half, the number of control wafers used is saved by at least half, and the time is saved by at least half. Thus, the production efficiency is greatly improved.

In some embodiments, the nozzle assembly further comprises a plurality of liquid channels and each nozzle is in connected with at least one of the liquid channels. Exemplarily, referring to FIG. 2, the first nozzle 20 is in connected with a first liquid channel 24, and the first liquid channel 24 feeds a cleaning agent, for example chemical cleaning liquid SC1, to the first nozzle 20. The second nozzle 21 is in connected with a second liquid channel 25, and the second liquid channel 25 feeds a cleaning agent, for example pure water, to the second nozzle 21.

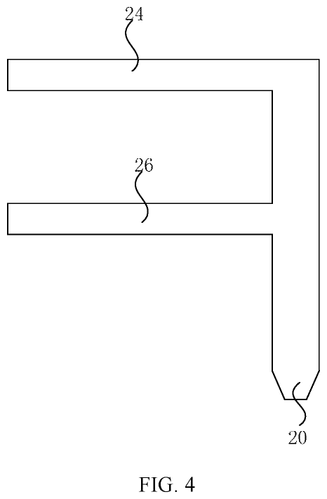

In some embodiments, the nozzle used to spray the chemical cleaning liquid needs to be cleaned regularly, to remove the remaining chemical cleaning liquid and avoid its crystallization which affects the subsequent operation. Therefore, referring to FIG. 4 which is a schematic cross-sectional structure diagram of the nozzle and liquid channel of the nozzle assembly according to a third embodiment of the present disclosure, in this embodiment, the first nozzle 20 is a chemical cleaning liquid nozzle, and the chemical cleaning liquid nozzle is in connected with two liquid channels (i.e., a first liquid channel 24 and a third liquid channel 26). The first liquid channel 24 feeds chemical cleaning liquid to the first nozzle 20, and the second liquid channel 25 feeds cleaning water, for example, pure water, to the first nozzle 20. When the chemical cleaning liquid is fed to the first nozzle 20 through the first liquid channel 24 and after sprayed, the first liquid channel 24 may be closed and the third liquid channel 26 may be opened to clean the first nozzle 20. For example, the first liquid channel 24 is closed through a valve provided on the first liquid channel 24, and the third liquid channel 26 is opened through a valve provided on the third liquid channel 26.

It was also found that, for some cleaning liquid, such as chemical cleaning liquid SC1, the rate in etching the wafer is low when the temperature is low. As an existing method to heat the cleaning liquid, usually, the cleaning liquid is heated in a buffer tank. The disadvantage is that, on one hand, it is energy-consuming; and on the other hand, a large amount of NH₃ and O₂ will overflow, which will cause the cleaning liquid to fail and cause the flowmeter to be stuck. Thus, it is impossible to accurately control the flow of the cleaning liquid.

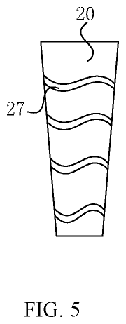

In view of this, the present disclosure further provides a fourth embodiment. Referring to FIG. 5, a heating element is provided on the outer surface of at least one of the nozzles to heat the cleaning liquid flowing through the nozzle. For example, a heating element 27 is provided on the outer surface of the first nozzle 20. When the cleaning liquid flows through the first nozzle 20, the heating element 27 heats the cleaning liquid to increase the temperature of the cleaning liquid, thereby increasing the etching rate of the cleaning liquid.

In some embodiments, the heating element 27 is a heating wire and the heating wire is wound on the outer surface of the first nozzle 20. In other embodiments of the present disclosure, the heating element 27 may be other heating devices.

In some embodiments, the heating temperature of the heating element 27 is 40° C. to 60° C. This temperature setting can increase the temperature of the cleaning liquid without causing the cleaning liquid to fail, thereby greatly increasing the etching rate of the cleaning liquid and increasing the productivity.

The present disclosure further provides a semiconductor equipment comprising the nozzle assembly as described above. The semiconductor equipment may be an etching device commonly used in a semiconductor manufacturing process.

Those skilled in the art will readily think of other implementations of the present disclosure by considering the specification and practicing the disclosure disclosed herein. The present disclosure is intended to encompass any variations, uses, or adaptive changes of the present disclosure. These variations, uses, or adaptive changes follow the general principles of the present disclosure and include common knowledge or conventional technical means in the technical field that are not disclosed in the present disclosure. The specification and the embodiments are just exemplary, and the true scope and spirit of the present disclosure are defined by the appended claims.

It should be understood that the present disclosure is not limited to the precise structures that have been described above and shown in the drawings, and various modifications and changes may be made without departing from its scope. The scope of the present disclosure is defined only by the appended claims.

### INDUSTRIAL APPLICABILITY

In the solution of the present disclosure, a spacer is provided between adjacent nozzles to maintain the distance between two adjacent nozzles within a preset range, so as to prevent two adjacent nozzles from getting too close or too far during the manufacturing process. The cleaning effect of the wafer surface is improved, organics, particles or peeled films are effectively removed, and the yield of wafers is improved.

What is claimed is:

1. A nozzle assembly, comprising:
at least two nozzles;
at least one spacer, connecting two adjacent nozzles so that the distance between the two adjacent nozzles is within a preset range; and
a robot arm, connected with one of the nozzles and configured to drive the at least two nozzles to move.

2. The nozzle assembly according to claim 1, wherein the spacer has a fixed length.

3. The nozzle assembly according to claim 1, wherein the spacer is a telescopic structure with a variable length.

4. The nozzle assembly according to claim 1, wherein the preset range of the distance is 0.4 mm to 1 mm.

5. The nozzle assembly according to claim 1, wherein the nozzle assembly further comprises a plurality of liquid channels, and each nozzle is in connected with at least one of the liquid channels.

6. The nozzle assembly according to claim 5, wherein the nozzle comprises a chemical cleaning liquid nozzle, and the chemical cleaning liquid nozzle is in connected with two liquid channels to respectively feed cleaning water and chemical cleaning liquid to the chemical cleaning liquid nozzle.

7. The nozzle assembly according to claim 1, wherein a heating element is provided on the outer surface of at least one of the nozzles, to heat the cleaning liquid flowing through the nozzle.

8. The nozzle assembly according to claim 7, wherein the heating element is a heating wire, and the heating wire is wound on the outer surface of the nozzle.

9. The nozzle assembly according to claim 7, wherein the heating temperature of the heating element is 40° C. to 60° C.

10. A semiconductor equipment, comprising the nozzle assembly according to claim 1.
